(19) United States
(12) Patent Application Publication
(10) Pub. No.: US 2026/0047070 A1
(43) Pub. Date: Feb. 12, 2026

(54) INTEGRATION METHOD OF VERTICAL DRAM WITH PERIPHERY CIRCUIT

(71) Applicant: TOKYO ELECTRON LIMITED, Tokyo (JP)

(72) Inventors: Sunghil LEE, Albany, NY (US); Soo Doo CHAE, Albany, NY (US); Hojin KIM, Albany, NY (US); Yen-Tien LU, Albany, NY (US); Arkalgud R. SITARAM, Albany, NY (US)

(73) Assignee: TOKYO ELECTRON LIMITED, Tokyo (JP)

(21) Appl. No.: 18/795,822

(22) Filed: Aug. 6, 2024

(51) Int. Cl. H10B 12/00; H01L 23/00; H01L 25/18; H01L 29/423; H01L 29/786; H10B 80/00

(52) U.S. Cl. CPC H10B 12/315; H01L 24/05; H01L 24/08; H01L 25/18; H10B 12/482; H10B 12/485; H10B 12/488; H10B 12/50; H10B 80/00; H10D 30/6728; H10D 30/6735; H01L 2224/05083; H01L 2224/05541; H01L 2224/05554; H01L 2224/0801; H01L 2224/08145; H01L 2924/1436

(57) ABSTRACT

A semiconductor device including a transistor region including vertical transistors arranged in an array to form a memory array area, and word lines connected to the vertical transistors. A capacitor region is formed within the memory array area above the transistor region and including vertical capacitors vertically connected to the vertical transistors through capacitor contacts. Bit lines are formed below the transistor region and vertically connected to the vertical transistors, the word lines and bit lines being arranged to form a matrix configuration within the memory array area. Backside contacts are formed within the memory array area, each backside contact connected to either a respective word line or a respective bit line and extending vertically to below the bit lines.

### FIELD OF THE INVENTION

This disclosure relates to semiconductor fabrication and, in particular, to a method of forming a semiconductor device and a method of integrating the semiconductor device with a peripheral circuit.

### BACKGROUND

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication nodes. Semiconductor device fabricators have expressed a desire for three-dimensional (3D) semiconductor circuits in which transistors are stacked on top of each other.

The density of vertical stacked DRAM has been remarkably increased due to the reduced size of memory cells. Currently, 4F² vertical DRAM has been obtained by using vertical channel transistors for the memory cells. However, such cells and the peripheral logic circuitry are typically formed on the same semiconductor substrate which requires a larger area on the semiconductor substrate. The continuous demand for higher capacity and performance in computer memory places constant pressure on the DRAM industry to achieve advances in density, speed, power efficiency and other areas.

### SUMMARY

The present disclosure provides a method of fabricating a vertical DRAM device by connecting the DRAM cell to a periphery circuit through hybrid bonding.

One aspect (1) of the disclosure provides a semiconductor device, including a transistor region including vertical transistors arranged in an array to form a memory array area, and word lines connected to the vertical transistors. A capacitor region formed within the memory array area above the transistor region and including vertical capacitors vertically connected to the vertical transistors through capacitor contacts. Bit lines are formed below the transistor region and vertically connected to the vertical transistors, wherein the word lines and bit lines are arranged to form a matrix configuration within the memory array area. Backside contacts are formed within the memory array area, each backside contact connected to either a respective word line or a respective bit line and extending vertically to below the bit lines.

Aspect (2) includes the semiconductor device of aspect (1), wherein the vertical transistors include Gate All Around (GAA) transistors arranged in an array.

Aspect (3) includes the semiconductor device of aspect (2), wherein each word line is connected to gate structures of adjacent GAA transistors.

Aspect (4) includes the semiconductor device of aspect (1), wherein the bit lines and word lines have a pitch of approximately 30-40 nm.

Aspect (5) includes the semiconductor device of aspect (1), wherein the backside contacts include at least one word line contact connected to a respective word line and extending vertically to pass through in-between two adjacent bit lines.

Aspect (6) includes the semiconductor device of aspect (1), wherein the backside contacts include: a plurality of word line contacts formed within the memory array area, each word line contact being connected to a respective word line and extending vertically to below the bit lines; and a plurality of bit line contacts formed within the memory array area, each bit line contact being connected to a respective bit line and extending vertically to below the bit lines.

Aspect (7) includes the semiconductor device of aspect (6), further including a plurality of wafer bonding pads formed within the memory array area below the backside contacts, each wafer bonding pad being connected to a respective word line contact or bit line contact.

Aspect (8) includes the semiconductor device of aspect (7), wherein each of the wafer bonding pads includes at least one of copper (Cu), aluminum (Al), or tungsten (W).

Aspect (9) includes the semiconductor device of aspect (7), wherein each of the wafer bonding pads has a diameter of approximately 0.5 μm or less.

Aspect (10) includes the semiconductor device of aspect (7), further including a peripheral circuit wafer which is hybrid bonded to a surface including the wafer bonding pads, the peripheral circuit wafer including a plurality of peripheral circuit components connected to the word line contacts and bit line contacts through the wafer bonding pads.

Aspect (11) includes the semiconductor device of aspect (1), further including: a peripheral circuit wafer including a plurality of peripheral circuit components; and a hybrid bod interface which connects the peripheral circuit wafer to a wafer including the backside contacts such that the peripheral circuit components are electrically connected to the backside contacts.

Aspect (12) includes the semiconductor device of aspect (11) wherein the device is a 4F² dynamic random-access memory (DRAM) device.

Another aspect (13) provides a method of forming a semiconductor device. The method includes providing a memory circuit wafer which includes: a transistor region including vertical transistors arranged in a memory array area and word lines connected to the vertical transistors, a capacitor region formed in the memory array area above the transistor region and including vertical capacitors vertically connected to the vertical transistors through capacitor contacts, and bit lines formed below the transistor region and vertically connected to the vertical transistors, wherein the word lines and bit lines are arranged to form a matrix configuration within the memory array area. The method further includes forming a plurality of backside contacts formed within the memory array area, each backside contact being connected to either a respective word line or a respective bit line and extending vertically to below the bit lines.

Aspect (14) includes the method of aspect (13), wherein the forming word line contacts includes forming at least one word line contact that passes through in-between two adjacent bit lines.

Aspect (15) includes the method of aspect (14), wherein the forming at least one word line contact includes performing a self-aligned contact (SAC) etch process to form the at least one word line contact.

Aspect (16) includes the method of aspect (15), wherein the SAC etch process includes forming a hole having a diameter of approximately 15-20 nm.

Aspect (17) includes the method of aspect (13), further including forming a plurality of wafer bonding pads within the memory array area below the backside contacts, each wafer bonding pad being connected to a respective backside contact.

Aspect (18) includes the method of aspect (17), wherein the forming bonding pads includes forming bonding pads each having a diameter of less than 0.5 μm.

Aspect (19) includes the method of aspect (17), further including: providing a peripheral circuit wafer including peripheral circuit components; and hybrid bonding the peripheral circuit wafer to the memory circuit wafer below the backside contacts such that the peripheral circuit components are electrically connected to the backside contacts.

Aspect (20) includes the method of aspect (13), wherein the semiconductor device is a 4F² dynamic random-access memory (DRAM) device.

Aspect (21) includes the semiconductor device of aspect (1), wherein the vertical transistors include double-gate vertical transistors arranged in an array.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be increased or reduced for clarity of discussion.

FIG. 1 is a cross-sectional view of a portion of the semiconductor device, in accordance with exemplary embodiments of the disclosure.

FIGS. 2A and 2B are top views of a cell array in a semiconductor device, in accordance with exemplary embodiments of the disclosure.

FIG. 3 shows a side view of a cross-sectional of an integrated semiconductor device, in accordance with exemplary embodiments of the disclosure.

FIGS. 4A, 4B, 4C and 4D are cross-sectional views of a semiconductor device during a fabrication process of channels at various intermediate steps, in accordance with exemplary embodiments of the disclosure.

FIGS. 5A, 5B, 5C and 5D are cross-sectional views of the semiconductor device during a fabrication process of word lines at various intermediate steps, in accordance with exemplary embodiments of the disclosure.

FIGS. 6A, 6B and 6C are cross-sectional views of the semiconductor device during a fabrication process of capacitor contacts at various intermediate steps, in accordance with exemplary embodiments of the disclosure.

FIGS. 7A, 7B, 7C, 7D, 7E and 7F are cross-sectional views of the semiconductor device during a fabrication process of vertical pillar capacitors at various intermediate steps, in accordance with exemplary embodiments of the disclosure.

FIGS. 8A, 8B, 8C, 8D, 8E, 8F, 8G, 8H and 8I are cross-sectional views of the semiconductor device during a fabrication process of bit lines at various intermediate steps, in accordance with exemplary embodiments of the disclosure.

FIGS. 9A, 9B and 9C are cross-sectional views of the semiconductor device during a fabrication process of bit lines at various intermediate steps, in accordance with exemplary embodiments of the disclosure.

FIGS. 10A, 10B, 10C and 10D are cross-sectional views of the semiconductor device during a dual damascene fabrication process of a first hybrid bonding pad at various intermediate steps, in accordance with exemplary embodiments of the disclosure.

FIGS. 11A, 11B and 11C are cross-sectional views of the semiconductor device during an integration process at various intermediate steps, in accordance with exemplary embodiments of the disclosure.

FIGS. 12A and 12B are top views of a cell array in a semiconductor device, in accordance with one possible implementation of DRAM.

FIG. 13 is a cross-sectional view of the semiconductor device of FIGS. 12A-12B.

### DETAILED DESCRIPTION OF THE PREFERRED EMBODIMENTS

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Further, spatially relative terms, such as “top,” “bottom,” “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The order of discussion of the different steps as described herein has been presented for clarity's sake. In general, these steps can be performed in any suitable order. Additionally, although each of the different features, techniques, configurations, etc. herein may be discussed in different places of this disclosure, it is intended that each of the concepts can be executed independently of each other or in combination with each other. Accordingly, the present invention can be embodied and viewed in many different ways.

In the drawings, like reference numerals designate identical or corresponding parts throughout the several views. Additionally, as used herein, the words “a”, “an” and the like generally carry a meaning of “one or more”, unless stated otherwise.

Furthermore, the terms, “approximately”, “approximate”, “about” and similar terms generally refer to ranges that include the identified value within a margin of 20%, 10%, or preferably 5%, and any values therebetween.

3D integration, i.e., the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND, application to random logic designs is substantially more difficult. 3D integration for logic chips (CPU (central processing unit), GPU (graphics processing unit), FPGA (field programmable gate array, SoC (System on a chip)) is being pursued.

As noted in the Background, there is constant demand in the memory industry to achieve advances in density, speed, power efficiency and other performance parameters. With respect to DRAM, 4F² scale has already been achieved by implementing vertical pillar transistors (VPTs), but peripheral logic circuits remain laterally spaced from the memory cell. Specifically, a routine of implementation of 4F² vertical DRAM is a fusion bonding of cell array wafer and periphery circuit wafer. However, due to the fusion bonding scheme, the contacts would be placed at the extension of word lines and bit lines outside the cell area, resulting in undesirable area consumption.

To address the problems mentioned above, embodiments described herein include a method of processing a hybrid bonding through the wafer backside to connect the periphery circuit to the memory cells. Further, the configuration of the contacts for word lines and bit lines through the fine pitch of word/bit lines can enable hybrid bonding for the 4F² vertical DRAM device. Accordingly, word lines and bit lines can be connected to the periphery transistor vertically through the bonding pads without undesirable area penalty.

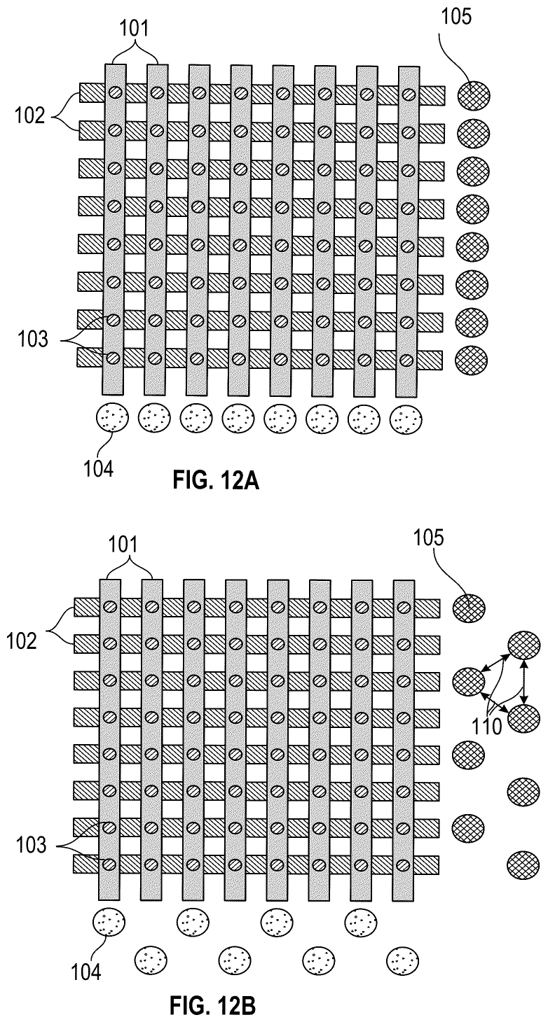

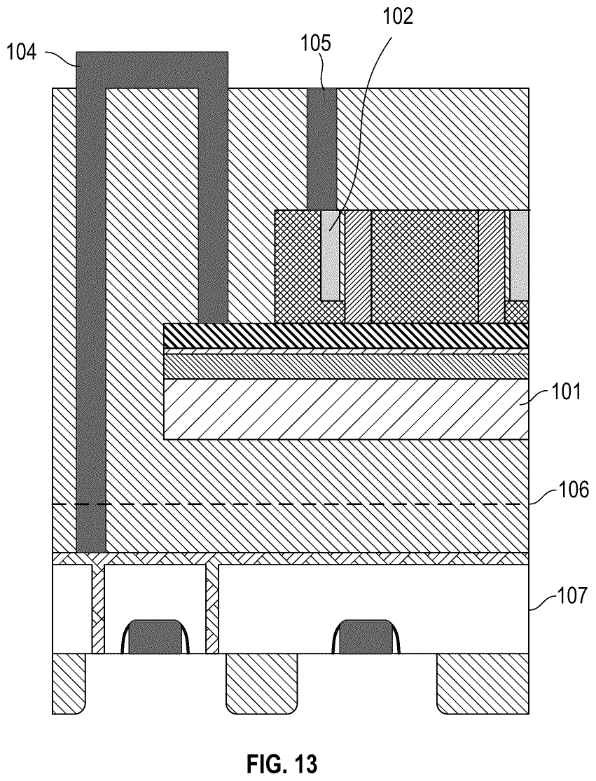

FIGS. 12A-12B are top views of a cell array and possible contact layout for a fusion bonded 4F² DRAM. FIG. 13 shows a cross-sectional view of a segment of a fusion bonded 4F² DRAM with a possible contact structure.

As shown in FIG. 12A, bit lines 101 each extend in a vertical direction and are arranged adjacent to one another in a horizontal direction, while word lines 102 each extend in a horizontal direction and are arranged vertically adjacent to one another. Capacitors 103 are formed to extend in a z direction (i.e., into the page) at the intersections of the bit lines 101 and the word lines 102. The bit line contacts 104 are formed adjacent to the bit lines 101, and the word line contacts 105 are formed adjacent to the word lines 102. As shown in FIG. 13, a segment of a memory cell is connected to peripheral circuitry 107 by fusion bonding to a bottom-bonded wafer as schematically illustrated by interface 106. The peripheral circuit 107 is under the memory cell. As shown, the bit lines 101 are connected to peripheral circuit of the bottom-bonded wafer through bit line contacts 104. Word lines 102 are similarly connected to the bottom-bonded wafer through the word line contacts 105 (partially shown).

As shown in FIGS. 12A and 13, the bit line contacts 104 and the word line contacts 105 may be laterally spaced from the cell array, which causes the bit line contacts 104 and word line contacts 105 occupy additional wafer space outside of the area of the memory cell. Further, in the configuration of FIG. 12A, where a word line/bit line pitch of about 30 nm to 40 nm is used a high aspect ratio (A/R) etch process used to form the plurality of contacts 104, 105 may be difficult to achieve with accuracy. As shown in FIG. 12B, contact pitch 110 may be relaxed to improve process reliability but such a configuration will result in further wafer area penalty. The present inventors have recognized that memory cell density can be potentially increased by placement of contacts within the area of the memory cell while also permitting hybrid bonding as discussed in more detail below.

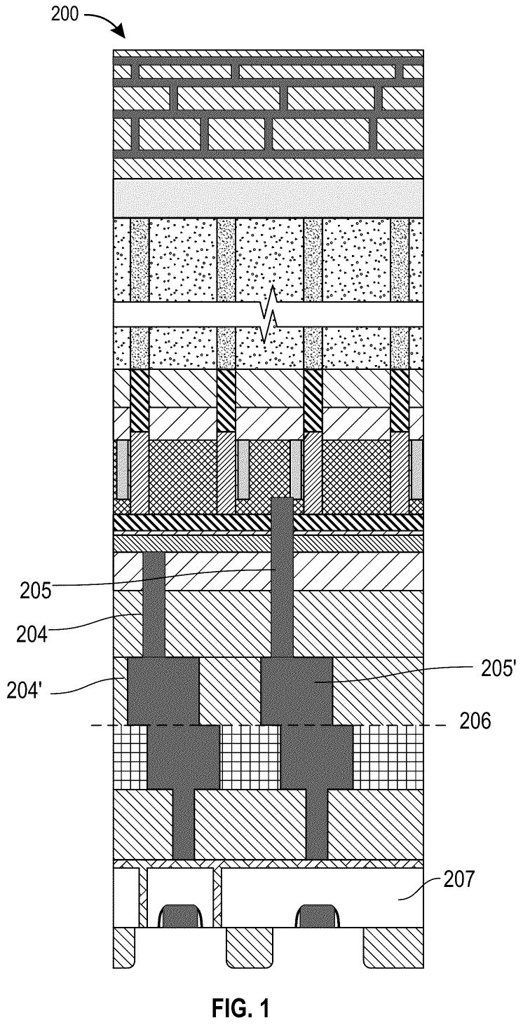

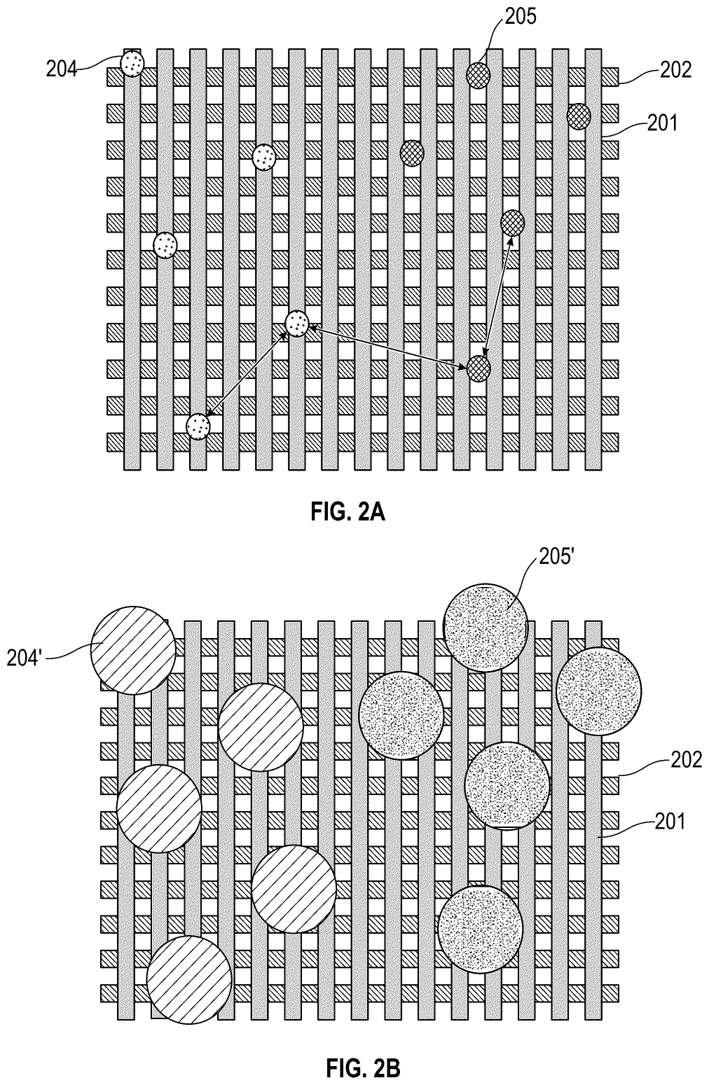

FIG. 1 shows a cross-sectional view of a 4F² DRAM device integrated by hybrid bonding in accordance with exemplary embodiments of the present disclosure. FIGS. 2A-2B are top views of a cell array and a contact layout for the hybrid bonded 4F² DRAM device.

As shown in FIG. 2A, bit lines 201 are arranged in a horizontal direction while word lines 202 are arranged in a vertical direction similar to FIG. 12A discussed above. Capacitors (not shown) are formed vertically at the intersections of the bit lines 201 and the word lines 202. Bit line contacts 204 are formed on the bit lines 201 within the area of the memory cell and word line contacts 205 are also formed within the memory cell area positioned between two adjacent bit lines 201.

Referring now the FIG. 1, the hybrid bonded DRAM device 200 is provided with a bond interface schematically depicted by the dashed line 206. The bit line contacts 204 and the word line contacts 205 are connected to peripheral circuitry 207 vertically through bonding pads 204′ and 205′ respectively. That is, the bit line contacts 204 and the word line contacts 205 can be formed within an area of the memory cell and do not occupy additional areas outside of the memory cell. As shown in FIG. 2B, this configuration can provide a bond pitch large enough to permit hybrid bonding. For example, given that 1M DRAM cells include 1024 bit lines and 1024 word lines, the total number of contacts will be 1024 (contacts for bit lines)+1024 (contacts for word lines)=2028. The total area of the cell for a 4F² DRAM is 1024*2F*1024*2F=(1024*2F)², and the bond area for each contact is thus (1024*2F)²/(1024+1024)=2048*F². If F=10 nm, then the bond area for each contact will be 204,800 nm², and the bond pitch will be sqrt (204,800 nm²)=453 nm=˜0.5 μm. Thus, the present inventors recognized that a 4F² DRAM having a word line/bit line pitch of 30 nm˜40 nm can permit a contact layout with large enough pitch to enable a bond pitch, for example less than or equal to approximately 0.5 μm, which is suitable for hybrid bonding.

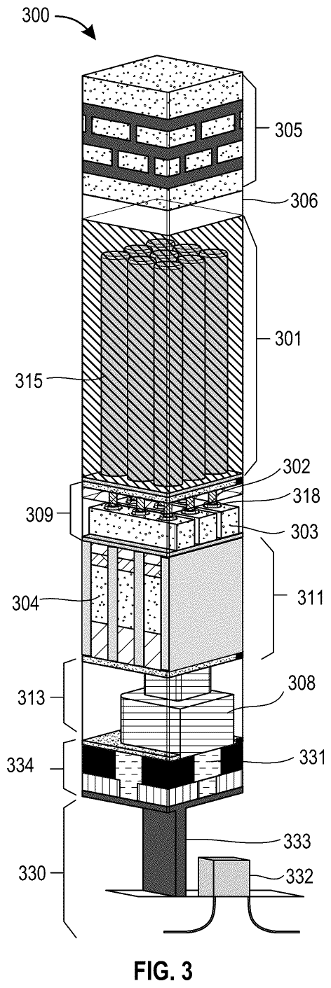

FIG. 3 shows a perspective view of a cross-sectional of an integrated semiconductor device (4F² vertical DRAM device) in accordance with an example embodiment of the present disclosure. The 4F² vertical DRAM device 300 includes a capacitor region 301 and a back end of line (BEOL) region 305 provided above the capacitor region. A word line (WL) transistor region 309, bit line (BL) region 311 (which also serves as a contact region) and bonding pad region 313 are provided below the capacitor region 301. In the embodiment of FIG. 3, a peripheral circuit region 330 is connected to the bonding pad region 313 through the bonding pad region 334 of the peripheral circuit wafer by wafer bonding as discussed further below.

The back end of line (BEOL) stack 305 can be deposited on a first oxide layer 306 formed over the capacitor region 301. The 4F² vertical DRAM device 300 can be connected to peripheral circuit 330 through backside contacts (not shown) which connect the bit lines and word lines to bonding pads 308 and bonding pads 331 of the peripheral circuitry. The peripheral circuit 330 can include a transistor 332 and metal interconnect 333. This configuration advantageously saves space by vertically connecting the 4F² vertical DRAM device 300 and the peripheral circuitry 330 within the area of the memory cell.

In an embodiment, each cell transistor in region 309 can be a vertical transistor such as a vertical Gate-All-Around (GAA) transistor that includes a vertical channel structure 318. Alternatively, the vertical transistor may be a double-gate vertical transistor. Each transistor in region 309 can be surrounded by a word line 303, which can be arranged in a row. Each doped silicon region 302 can be formed on top of the channel structure 318. Each doped silicon region 302 can be a contact region that connects the capacitor region 301 to a transistor.

In an embodiment, the capacitor region 301 can include multiple capacitors 315 positioned above the transistors in region 309. Each capacitor 315 can contact the respective channel 318 through the doped silicon region 302. The first oxide layer 306 can be deposited on top of the capacitor region 301.

In an embodiment, the bit lines 304 can be positioned below the word lines 303. Back side contacts (not shown) are formed within the bit line region 311 on top of bonding pads 308. Accordingly, the peripheral circuit 330 can be connected to the bit lines 304 and the word lines 303 vertically through bonding pads 331, bonding pads 308 and back side contacts within the bit line region 311.

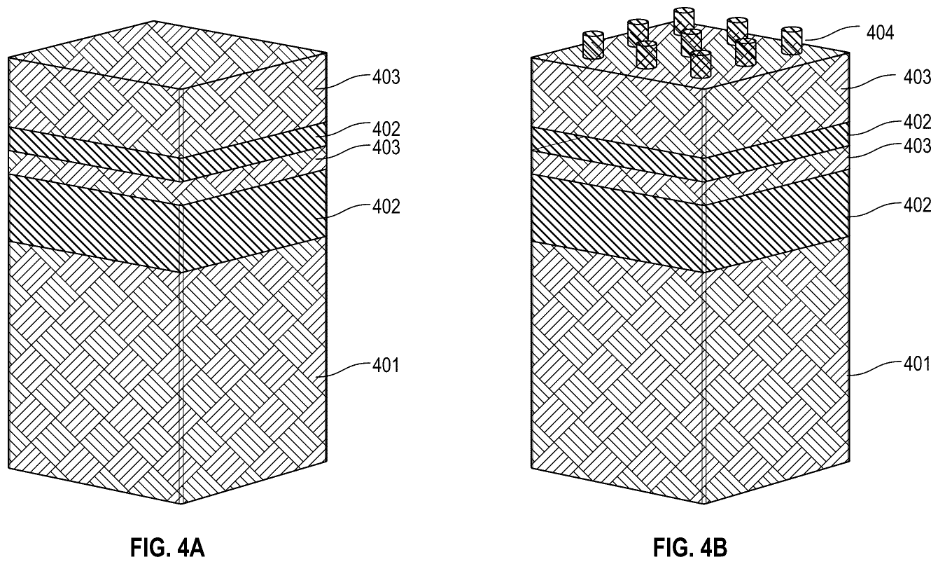

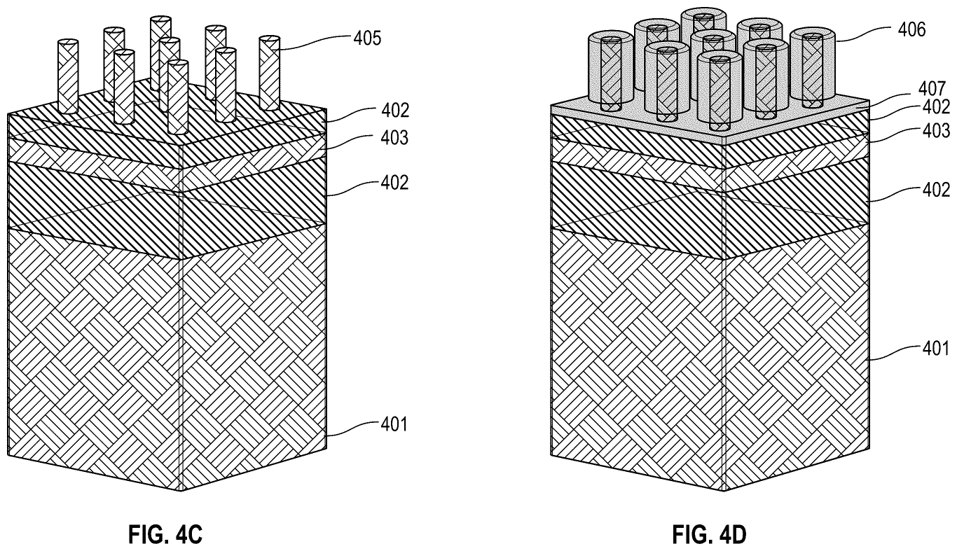

FIGS. 4A-4D show cross-sectional views of various intermediary steps of an exemplary method for fabricating channels 405 of the 4F² vertical DRAM device according to example embodiments of the present disclosure.

As shown in FIG. 4A, a substrate 401 of Silicon (Si) is provided. The substrate 401 can also be any other suitable substrate, such as Germanium (Ge), Silicon Germanium (SiGe), or silicon-on-insulator (SOI) substrate. An initial stack of a first semiconductor layer (e.g., SiGe) 402 and a second semiconductor layer (e.g., Si) 403 can be alternatively deposited on the substrate 401 as shown. In FIG. 4B, an etch mask with multiple channel patterns 404 can be formed on top of the initial stack.

An etching process can be applied to etch the upper second semiconductor layer 403 with etch stop at the underlying semiconductor layer 402. The etch mask can be stripped off and removed to provide the vertical channel structures 405 as shown in FIG. 4C.

As shown in FIG. 4D, material for a gate structure of the GAA transistor (or alternatively any type of vertical transistor) can be formed to surround each channel structure 405. For example, a gate dielectric layer 407 can be deposited on channels 405 as well as on top of the upper first semiconductor layer 402, followed by deposition of a gate metal layer on the channels 405. The gate material is shown transparent in FIG. 4D to clarify the underlying channel structure. The channel structure 405 having the gate structure thereon is referred to as a channel 406 herein. The gate dielectric material can be any suitable oxide material such as silicon dioxide (SiO₂), Hafnium oxide (HfO), Titanium oxide (TiO), for example. The gate metal gate layer can be Titanium Nitride (TiN), for example.

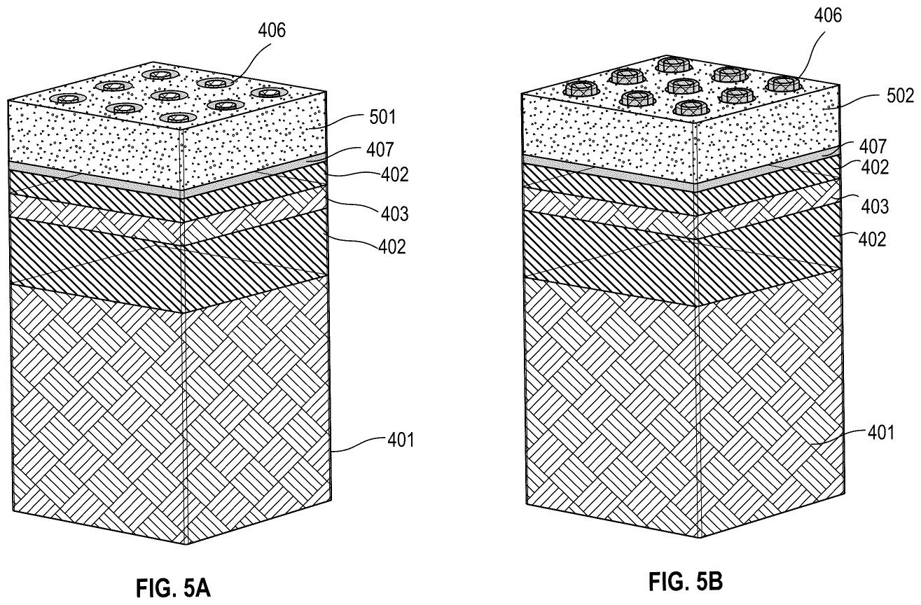

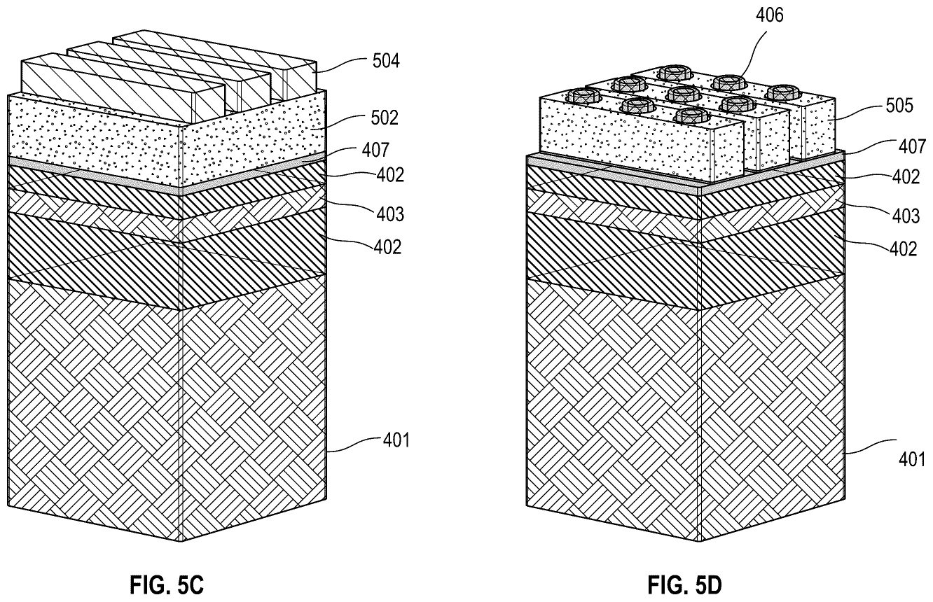

FIGS. 5A-5D show cross-sectional views of various intermediary steps of an exemplary method for fabricating word lines 505 of the 4F² vertical DRAM device according to embodiments of the present disclosure.

As shown in FIG. 5A, a first metal layer 501 can be deposited on top of the second oxide layer 407 to fill the spaces surrounding the channels 406. The first metal layer can include any suitable metal material such Tungsten (W). As shown in FIG. 5B, the first metal layer 501 can be recessed along a central axis of the channels to provide a thinned metal layer 502 to expose an end of the transistor channels 406. As shown in FIG. 5C, an etch mask with patterns 504 can be formed on the first metal layer 502, and an etching process can be applied to etch the first metal layer 502 to form the word lines 505. Each word line 505 can be connected to the gate structure 406 of each transistor in a row. The etch mask is stripped off and removed to provide the structure shown in FIG. 5D.

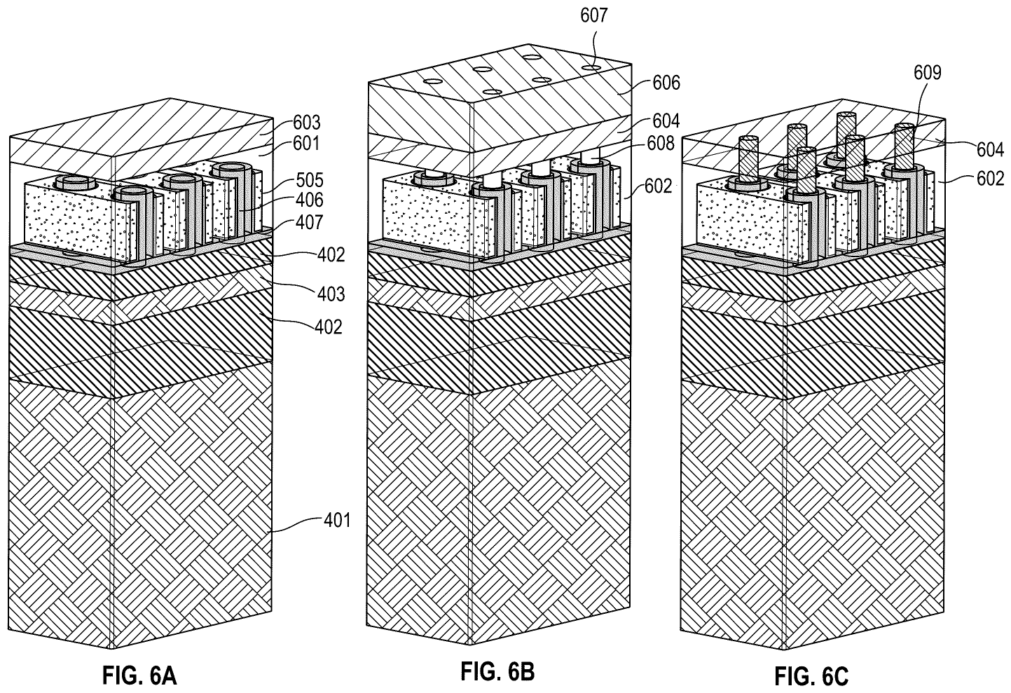

FIGS. 6A-6C show cross-sectional views of various intermediary steps of an exemplary method for fabricating multiple capacitor contacts 608 of the 4F² vertical DRAM device according to the embodiments of the present disclosure.

As shown in FIG. 6A, interlayer oxide layers 601 can be deposited on the second oxide layer 407 to fill the spaces between word lines 505 and channels 406. An uppermost layer of the interlayer oxide layers 601 can be positioned above the channels 406 shown as laterally exposed. A first nitride layer 603 can be deposited on top of the interlayer oxide layers 601. The first nitride layer can include any suitable nitride material such as Silicon Nitride (SiN). As shown in FIG. 6B, an etch mask 606 can be formed on top of the first nitride layer 603 and patterned to include multiple holes 607. An etching process can be applied to etch the first nitride layer 603 and a portion of the interlayer oxide layers 601 to form structures 602 and 604 having holes therein. Holes are schematically depicted as 608.

As shown in FIG. 6C, poly silicon can be filled to the holes 608 to form the multiple doped silicon regions 609 as capacitor contacts. The multiple doped silicon regions 609 can pass through the first nitride layer 604 and a portion of the interlayer oxide layers 602. Any overburdened nitride material can be removed by a surface planarization process such as a chemical mechanical polishing (CMP) process. FIG. 6C shows the structure after the etch mask 606 is stripped off and removed.

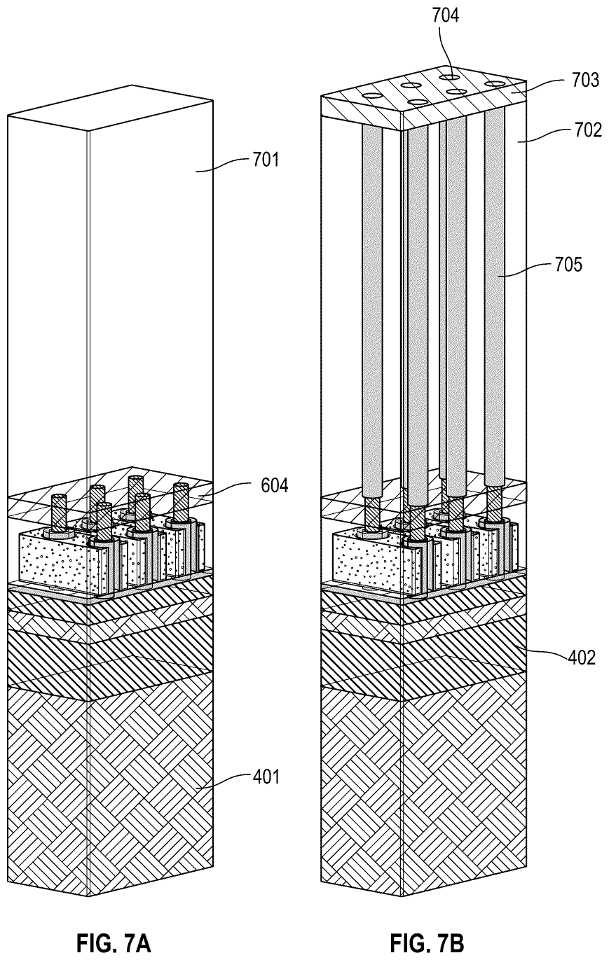

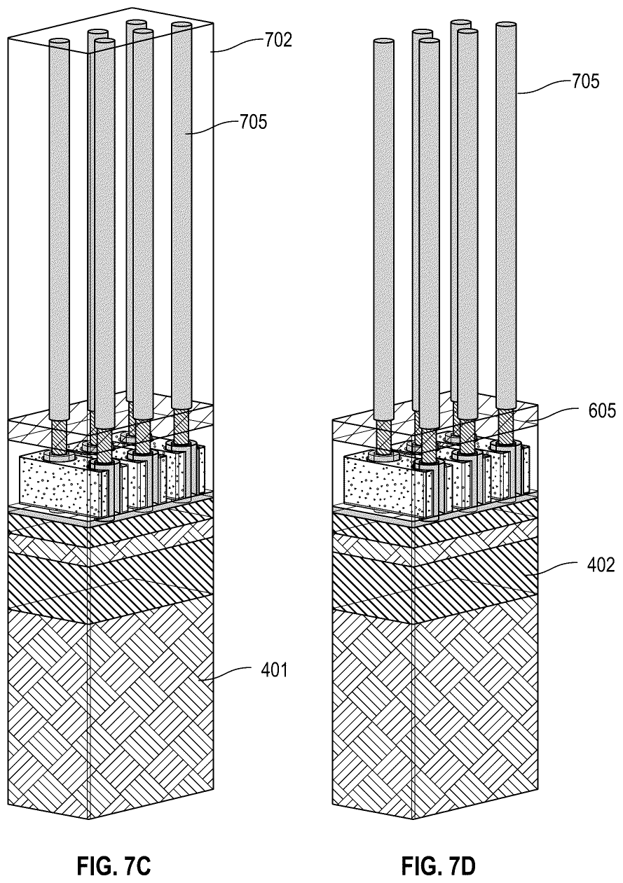

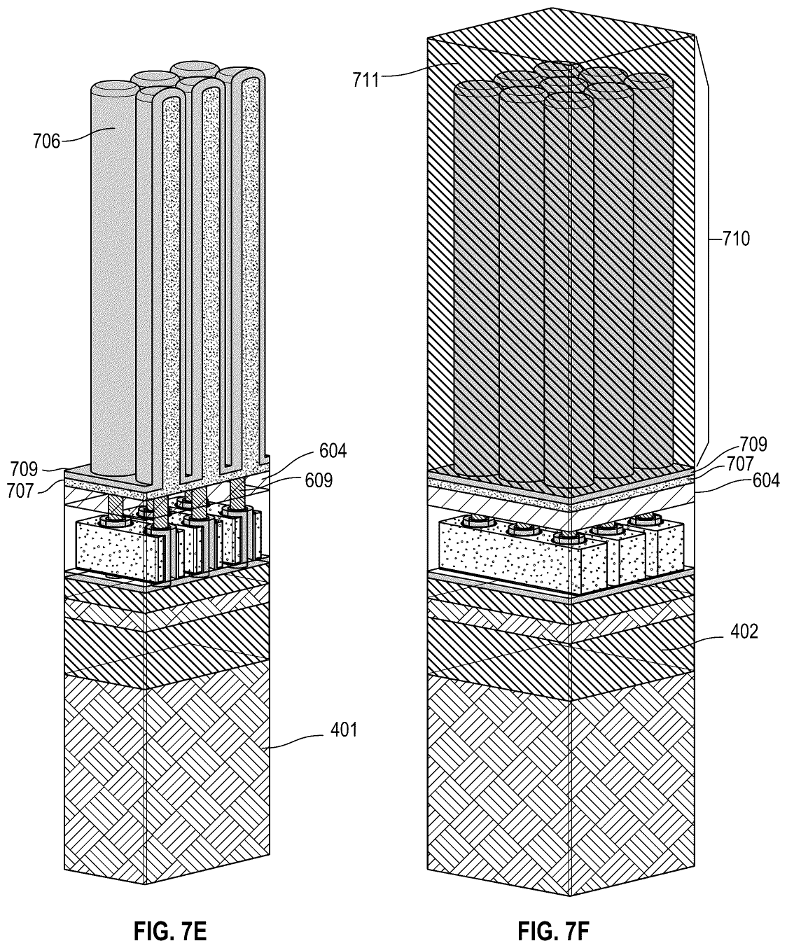

FIGS. 7A-7F show cross-sectional views of various intermediary steps of an exemplary method for fabricating vertical pillar capacitors 706 of the 4F² vertical DRAM device according to the embodiments of the present disclosure. In some embodiments, a capacitor structure similar to that of conventional DRAM devices may be used.

As shown in FIG. 7A, insulating films 701 can be deposited on top of the first nitride layer 604. The insulating films can include an oxide or any other suitable materials. As shown in FIG. 7B, an etch mask 703 with a pattern of holes 704 can be formed on top of the insulating films. Holes 704 which are used to etch holes into the insulating film 701, and a conductive material (e.g., TiN) can be filled into the etched holes to form pillar structures 705 within the surrounding insulator 702. As shown in FIG. 7C, the etch mask is stripped off and removed, and a CMP process can be performed to remove any overburdened conductive material. A selective etching process can be applied to etch the insulating films 702 to expose the multiple pillars 705 as shown in FIG. 7D.

As shown in FIG. 7E, dielectric film 707 can be deposited to cover the pillars 705 and the surface of the first nitride layer 604. The dielectric film can include any suitable oxide materials, for example. Conductive material 709 can be further deposited on the dielectric films 707. Accordingly, vertical pillar capacitors 706 can be formed and connected to the vertical GAA transistors through capacitor contacts 609. As shown in FIG. 7F, semiconductor films (e.g., Silicon Germanium (SiGe)) 711 can be deposited over the conductive layer 709 to fill spaces surrounding the capacitors 706. An upper layer of the semiconductor films 711 can be positioned above the capacitors 706. Any overburdened semiconductor material can be removed by a surface planarization process, such as a CMP process, to provide a capacitor region 710 shown in FIG. 7F.

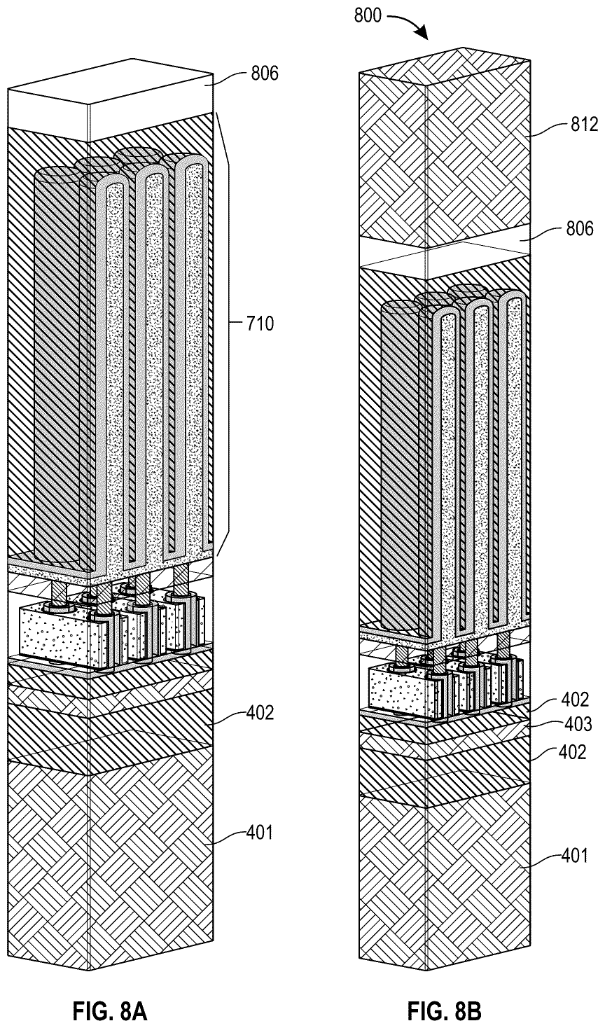

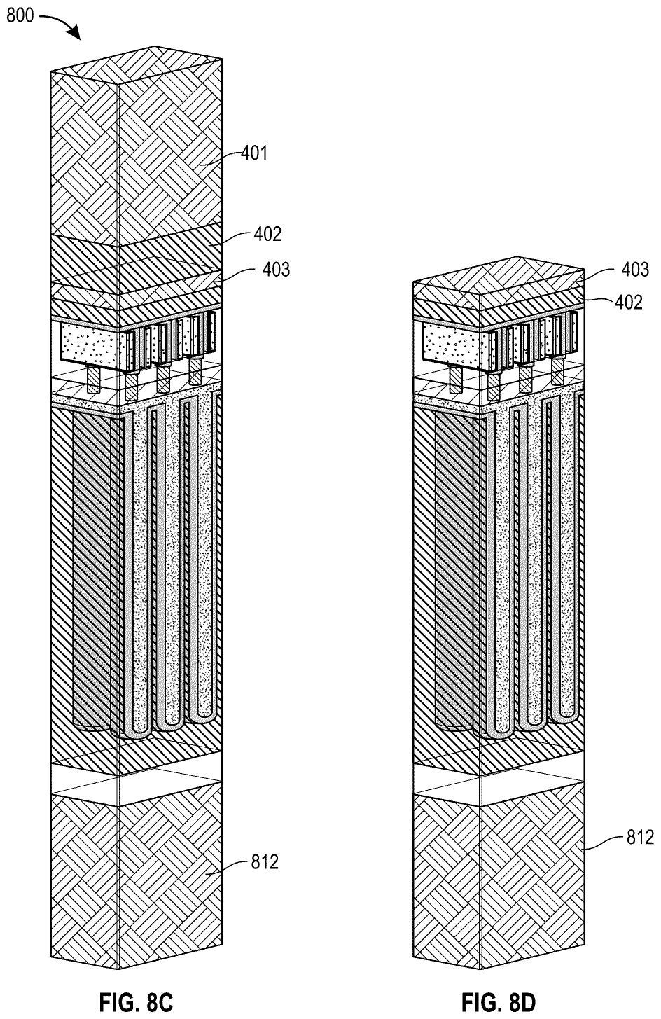

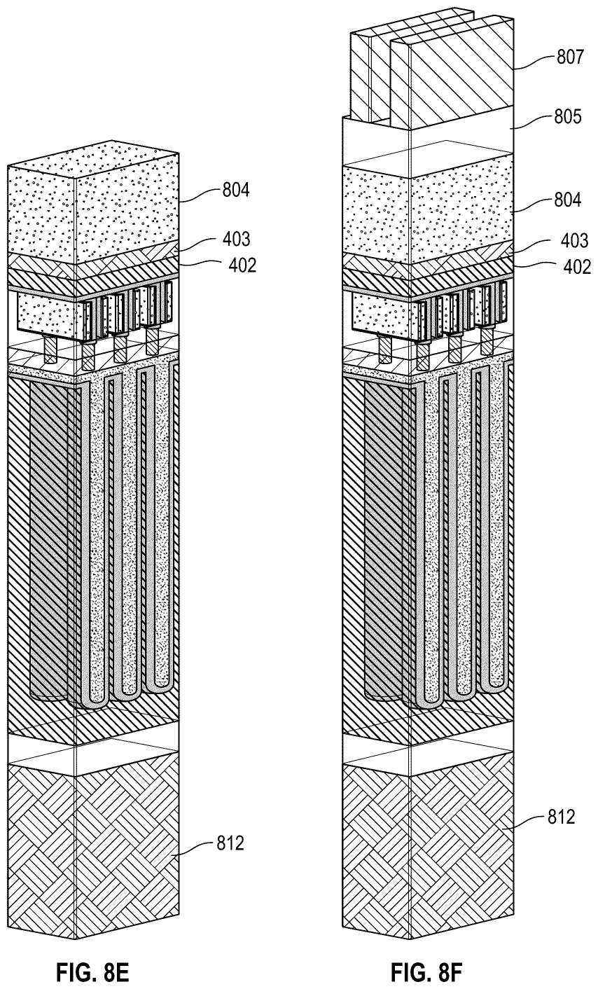

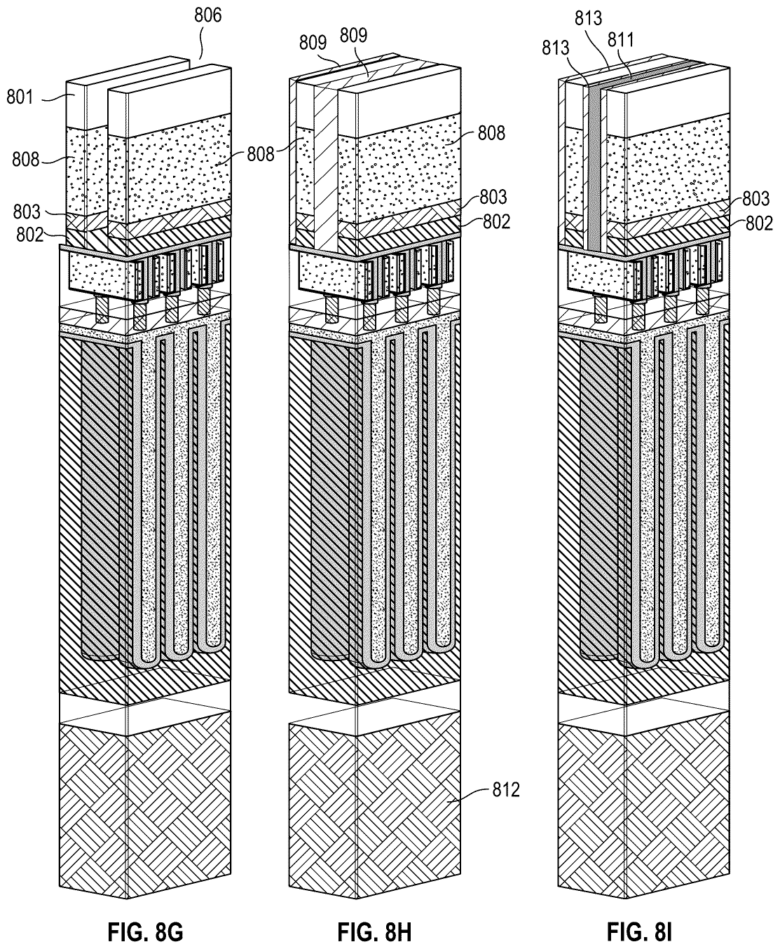

FIGS. 8A-8I show cross-sectional views of various intermediary steps of an exemplary method for fabricating bit lines 808 of the 4F² vertical DRAM device according to embodiments of the present disclosure.

As shown in FIG. 8A, the first oxide layer 806 can be formed on top of the capacitor region 710. The first oxide layer 806 can include any suitable oxide materials such as Silicon Dioxide (SiO₂). As shown in FIG. 8B, a wafer 812 can be bonded to the first oxide layer 806 by fusion bonding or any suitable wafer bonding method. The wafer 812 can include any suitable material such as Si.

As shown in FIG. 8C, the DRAM structure 800 can be temporarily flipped. After the flipping process, the substrate 401 is positioned at the top of the DRAM structure 800, and the wafer 812 is placed at the bottom of the DRAM structure 800. Accordingly, the backside surface of the substrate 401 is now facing up. As shown in FIG. 8D, a wafer backside grinding process can be applied to remove the substrate 401 and the lower first semiconductor layer 402 such that the lower second semiconductor layer 403 is exposed.

As shown in FIG. 8E, a second metal layer 804 can be deposited on top of the lower second semiconductor layer 403. The second metal layer 804 can include any suitable metal material such as W. A first hard mask layer 805 can be deposited to cover the second metal layer 804. The first hard mask 805 can include any suitable nitride material such as SiN.

As shown in FIG. 8F, an etching mask 807 with patterns can be formed on the first hard mask layer 805. An etching process can be applied to etch the first hard mask 805 which is then used to etch the second metal layer 804, the lower second semiconductor layer 403 and the lower first semiconductor layer 402 to form first trenches. FIG. 8G shows the etched structure including etched hard mask 801, etched metal 808 etched second semiconductor layer 803 and etched first semiconductor layer 802 to form trench 806. Trench 806 extends vertically in-between bit lines 808 formed from the second metal layer. FIG. 8G shows the resulting structure with the etching mask 807 stripped off and removed.

As shown in FIG. 8H, nitride films 809 can be filled into the first trenches 806. The nitride films 809 can include any suitable material such as SiN. Another etching process can be applied to etch the nitride films 809 to form second trenches that extend vertically into the nitride films 809. As shown in FIG. 8I, and insulating film 811 of any suitable material (e.g., SiO₂) can be filed into the second trenches between the remaining nitride films 813. A CMP process can be performed to planarize the surface to remove any overburdened insulating films.

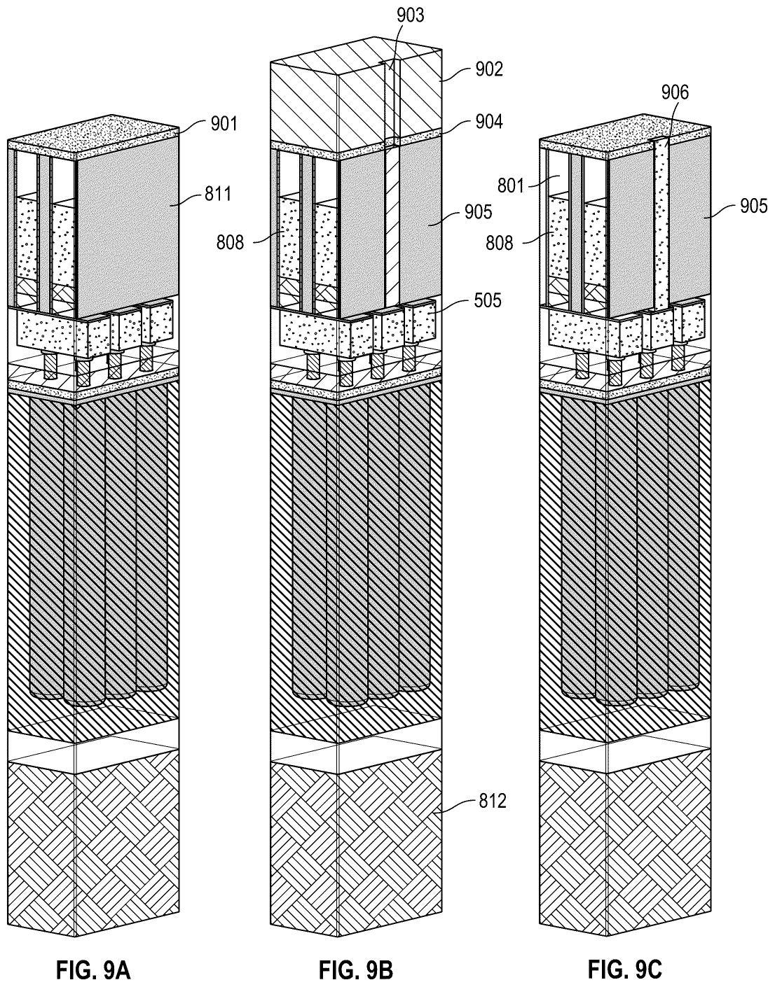

FIGS. 9A-9C show cross-sectional views of various intermediary steps of an exemplary method for fabricating contacts for word lines of the 4F² vertical DRAM device according to the embodiments of the present disclosure.

As shown in FIG. 9A, a second hard mask layer 901 can be deposited to cover the surface that has been planarized in the previous step. The second hard mask layer 901 can include any suitable nitride material such as SiN.

As shown in FIG. 9B, an etch mask 902 with patterns can be formed on top of the second hard mask 901. Patterning and high aspect ratio (A/R) etching can be applied to form holes 903 that pass through the insulating film 811 in-between the bit lines 808. In some embodiments, the hole size is 15-20 nm in diameter. A Self-Aligned Contact (SAC) with high selectivity hard mask is preferably used to provide the word line contact in-between bit lines with fine pitch. The present inventors recognized that a SAC high selectivity etch process against hard mask can provide accurate contact placement and minimal damage to bit lines even in case of photolithography mis-alignment. FIG. 9B shows the etched second hard mask 904 and etched insulating film 905 to form a hole 903 extending to the word lines 505.

A suitable metal material such as W can be filled into the holes 903 to form the contact 906 for the word lines 505. The etch mask 902 can be stripped off and removed, and a surface planarization process such as the CMP can be performed to planarize the surface to remove any overburdened metal material, as shown in FIG. 9C. While not shown in the figures, a similar process may be used to form contacts to the bit lines 808. Formation of contacts for bit lines 808 may use any suitable etch process.

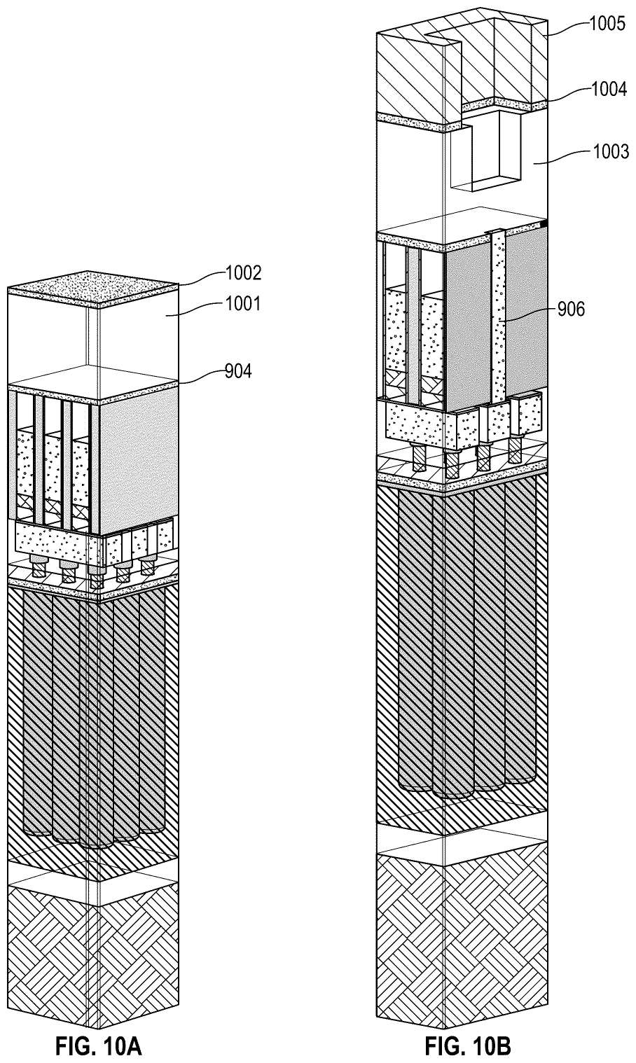

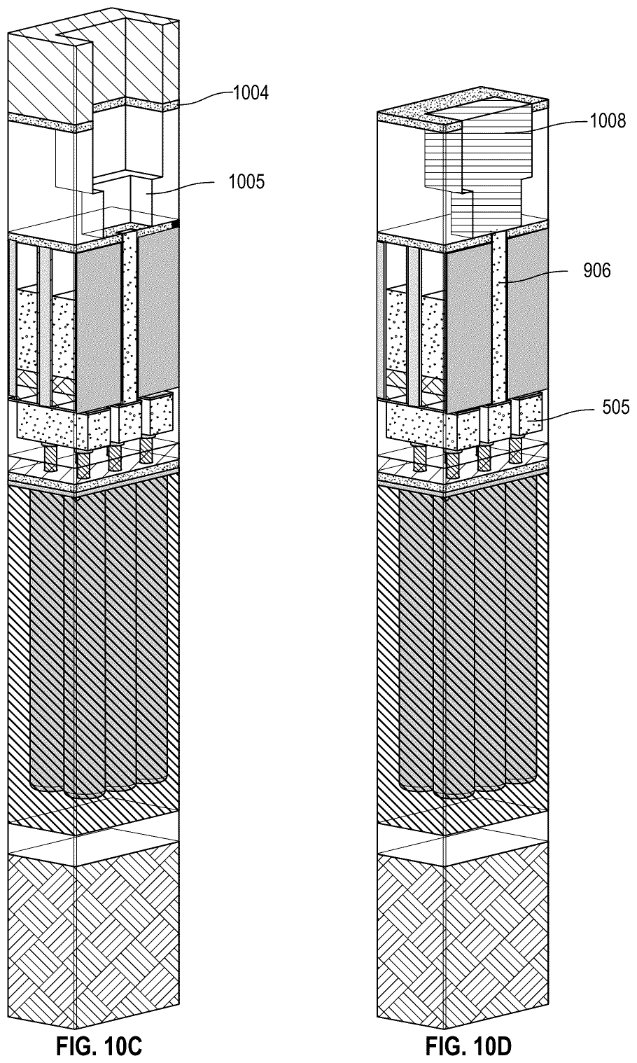

FIGS. 10A-10D show cross-sectional views of various intermediary steps of an exemplary method for a dual damascene fabrication process of a first hybrid bonding pad of the 4F² vertical DRAM device according to example embodiments of the present disclosure.

As shown in FIG. 10A, an oxide layer 1001 (e.g., SiO₂) can be formed on top of the second hard mask 904, and a nitride layer 1002 (e.g., SiN) can be deposited on the top surface of the oxide layer 1001. As shown in FIG. 10B, patterned mask 1005 is used to etch the nitride layer 1002 and the oxide layer 1001 to form patterned structures 1004 and 1003 respectively. An etching process can be further applied to etch the oxide 1001 to form the via-trench openings 1005, as shown in FIG. 10C.

As shown in FIG. 10D, a suitable metal material such as Copper (Cu) can be further filled into the via-trench openings 1005 to form hybrid bonding pads 008. The CMP process can remove excess Cu. The first bonding pad 1008 is connected to the contact 906 for the word line 505 as illustrated, but similar connections are made to bit lines.

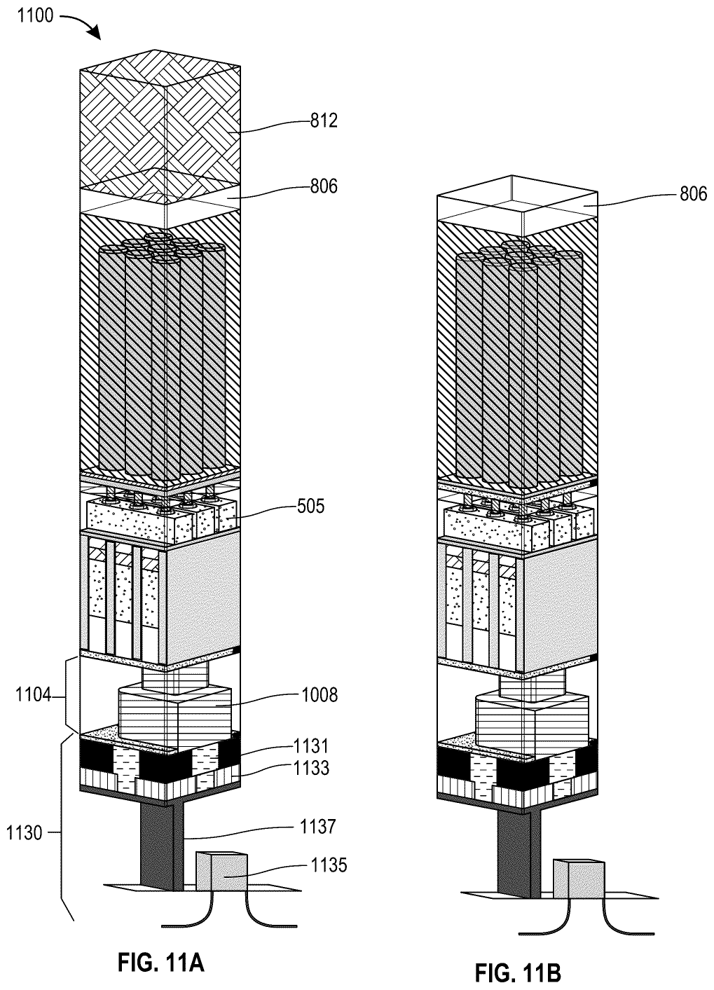

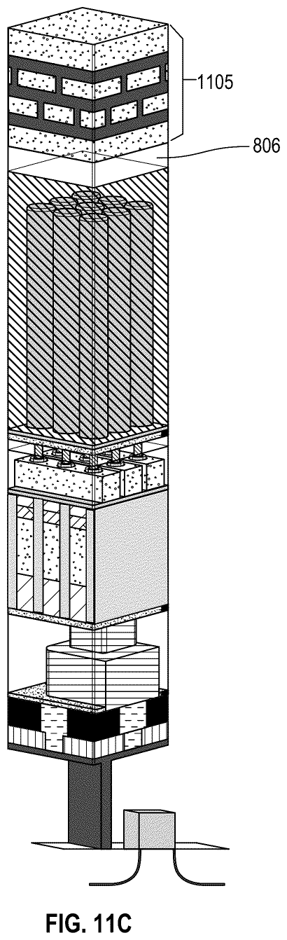

FIGS. 11A-11C show cross-sectional views of various intermediary steps of an exemplary method of integrating the 4F² vertical DRAM device with peripheral circuits and BEOL metal structure according to the embodiments of the present disclosure.

As shown in FIG. 11A, the DRAM device 1100 can be flipped back to its original position. After the flipping process, the wafer 812 is positioned on the top of the DRAM structure first oxide layer 806. Another wafer which includes peripheral circuitry and associated contacts can be placed below the first bonding pad 1008. The peripheral circuit wafer 1130 includes second bonding pad 1131 embedded into the insulating layer 1133. The peripheral circuit wafer 1103 and wafer 812 including the DRAM structure can be bonded together by a suitable hybrid bonding technique. Any suitable hybrid bonding technique may be used to simultaneously bond the conductor regions together and the insulative regions together. In the embodiment of FIG. 11, the first bonding pad 1008 is bonded to the second bonding pad 1131. Accordingly, the word lines 505 can be vertically connected to a peripheral circuit 1130 through the first bonding pad 1008 and the second bonding pad 1131. In an embodiment, the peripheral circuit 1130 can include a peripheral transistor 1135 and multiple periphery metal layers 1137.

As shown in FIG. 11B, a wafer grinding process can be performed to remove the wafer 812. After the grinding process, the top surface of the first oxide layer 806 is exposed. As shown in FIG. 11C, BEOL metal 1105 can be formed on top of the first oxide layer 806. In the semiconductor fabrication process, BEOL 1105 can be formed by depositing and etching metal layers. Accordingly, the DRAM device can be interconnected with wiring by deposited metalization layers in BEOL 1105.

The various embodiments described herein offer several advantages. While 4F² vertical DRAM can be implemented by bonding the cell array wafer and peripheral circuit through fusion bonding, which will place the contacts for word lines and bit lines outside the cell area, hybrid bonding can connect the word lines and the bit lines to the periphery circuit through bonding pads vertically inside the cell area. Therefore, the DRAM can be integrated without wasting the area outside of the cell area. Accordingly, the cell area size can be decreased, and the cell density can be increased.

In the preceding description, specific details have been set forth, such as a particular geometry of a processing system and descriptions of various components and processes used therein. It should be understood, however, that techniques herein may be practiced in other embodiments that depart from these specific details, and that such details are for purposes of explanation and not limitation. Embodiments disclosed herein have been described with reference to the accompanying drawings. Similarly, for purposes of explanation, specific numbers, materials, and configurations have been set forth in order to provide a thorough understanding. Nevertheless, embodiments may be practiced without such specific details. Components having substantially the same functional constructions are denoted by like reference characters, and thus any redundant descriptions may be omitted.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the invention. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives of the invention. Such variations are intended to be covered by the scope of this disclosure. As such, the foregoing descriptions of embodiments of the invention are not intended to be limiting. Rather, any limitations to embodiments of the invention are presented in the following claims.

What is claimed is:

1. A semiconductor device, comprising:
a transistor region comprising vertical transistors arranged in an array to form a memory array area, and word lines connected to the vertical transistors;
a capacitor region formed within the memory array area above the transistor region and comprising vertical capacitors vertically connected to the vertical transistors through capacitor contacts;
bit lines formed below the transistor region and vertically connected to the vertical transistors, wherein the word lines and bit lines are arranged to form a matrix configuration within the memory array area; and
backside contacts formed within the memory array area, each backside contact connected to either a respective word line or a respective bit line and extending vertically to below the bit lines.

2. The semiconductor device of claim 1, wherein the vertical transistors comprise Gate All Around (GAA) transistors arranged in an array.

3. The semiconductor device of claim 2, wherein each word line is connected to gate structures of adjacent GAA transistors.

4. The semiconductor device of claim 1, wherein the bit lines and word lines have a pitch of approximately 30-40 nm.

5. The semiconductor device of claim 1, wherein the backside contacts comprise at least one word line contact connected to a respective word line and extending vertically to pass through in-between two adjacent bit lines.

6. The semiconductor device of claim 1, wherein the backside contacts comprise:
a plurality of word line contacts formed within the memory array area, each word line contact being connected to a respective word line and extending vertically to below the bit lines; and
a plurality of bit line contacts formed within the memory array area, each bit line contact being connected to a respective bit line and extending vertically to below the bit lines.

7. The semiconductor device of claim 6, further comprising a plurality of wafer bonding pads formed within the memory array area below the backside contacts, each wafer bonding pad being connected to a respective word line contact or bit line contact.

8. The semiconductor device of claim 7, wherein each of the wafer bonding pads comprises at least one of copper (Cu), aluminum (Al), or tungsten (W).

9. The semiconductor device of claim 7, wherein each of the wafer bonding pads has a diameter of approximately 0.5 μm or less.

10. The semiconductor device of claim 7, further comprising a peripheral circuit wafer which is hybrid bonded to a surface including the wafer bonding pads, the peripheral circuit wafer comprising a plurality of peripheral circuit components connected to the word line contacts and bit line contacts through the wafer bonding pads.

11. The semiconductor device of claim 1, further comprising:
a peripheral circuit wafer comprising a plurality of peripheral circuit components; and
a hybrid bod interface which connects the peripheral circuit wafer to a wafer including the backside contacts such that the peripheral circuit components are electrically connected to the backside contacts.

12. The semiconductor device of claim 11 wherein the device is a 4F² dynamic random-access memory (DRAM) device.

13. A method of forming a semiconductor device, comprising:
providing a memory circuit wafer comprising:
a transistor region comprising vertical transistors arranged in a memory array area and word lines connected to the vertical transistors,
a capacitor region formed in the memory array area above the transistor region and comprising vertical capacitors vertically connected to the vertical transistors through capacitor contacts, and
bit lines formed below the transistor region and vertically connected to the vertical transistors, wherein the word lines and bit lines are arranged to form a matrix configuration within the memory array area; and
forming a plurality of backside contacts formed within the memory array area, each backside contact being connected to either a respective word line or a respective bit line and extending vertically to below the bit lines.

14. The method of claim 13, wherein the forming word line contacts comprises forming at least one word line contact that passes through in-between two adjacent bit lines.

15. The method of claim 14, wherein the forming at least one word line contact comprises performing a self-aligned contact (SAC) etch process to form the at least one word line contact.

16. The method of claim 15, wherein the SAC etch process comprises forming a hole having a diameter of approximately 15-20 nm.

17. The method of claim 13, further comprising forming a plurality of wafer bonding pads within the memory array area below the backside contacts, each wafer bonding pad being connected to a respective backside contact.

18. The method of claim 17, wherein the forming bonding pads comprises forming bonding pads each having a diameter of less than 0.5 μm.

19. The method of claim 17, further comprising:
providing a peripheral circuit wafer comprising peripheral circuit components; and
hybrid bonding the peripheral circuit wafer to the memory circuit wafer below the backside contacts such that the peripheral circuit components are electrically connected to the backside contacts.

20. The method of claim 13, wherein the semiconductor device is a 4F² dynamic random-access memory (DRAM) device.

21. The semiconductor device of claim 1, wherein the vertical transistors comprise double-gate vertical transistors arranged in an array.
